(19) United States
(12) Patent Application Publication
(10) Pub. No.: US 2005/0105328 A1
(43) Pub. Date: May 19, 2005

(54) Perpendicular MRAM with high magnetic transition and low programming current

(76) Inventor: Chiahua Ho, Hsinchu (TW)

Correspondence Address: MARTINE PENILLA & GENCARELLA, LLP, 710 LAKEWAY DRIVE, SUITE 200, SUNNYVALE, CA, 94085, US

(21) Appl. No.: 10/715,670

(22) Filed: Nov. 17, 2003

(51) Int. Cl. G11C 11/00

(52) U.S. Cl. 365/158

(57) ABSTRACT

An invention is provided for a magnetic random access memory (MRAM) cell. The MRAM cell includes a first wordline and a first bitline perpendicular to the wordline. Disposed at an intersection of the first wordline and the first bitline is an MTJ device having a perpendicular magnetic orientation. To program the MRAM cell, current is driven through the two bitlines and two wordlines that are adjacent to the memory cell. As a result, the MRAM cell has a high magnetic transition and low programming current.

### BACKGROUND OF THE INVENTION

1. Field of the Invention

This invention relates generally to computer storage and, more particularly, to a perpendicular magnetic random access memory having high magnetic transition and low programming current.

2. Description of the Related Art

Magnetic Random Access Memory (“MRAM”) is a non-volatile memory utilized for long-term data storage. MRAM devices perform read and write operations orders of magnitude faster than conventional long-term storage devices such as hard drives. In addition, MRAM devices are more compact and consume less power than other conventional long-term storage devices.

Memory cells of an MRAM are based on magnetic tunnel junction (MTJ) devices, which have two ferromagnetic layers separated by a thin insulating tunnel barrier. A spin-polarized tunneling of conduction electrons between the two ferromagnetic layers, based on the relative orientation of the magnetic moments of the two ferromagnetic layers, provides the magnetoresistance of an MTJ. A typical MRAM device includes an array of memory cells. Wordlines extend along rows of the memory cells, and bitlines extend along columns of the memory cells. Each memory cell is located at a cross point of a wordline and a bitline, and stores a bit of information as an orientation of a magnetization. The magnetization orientation of each memory cell assumes one of two stable orientations at any given time. These two stable orientations, parallel and anti-parallel, represent logic values of “1” and “0.” Supplying a current to a wordline and a bitline crossing a selected memory cell changes the magnetization orientation of a selected memory cell by creating two orthogonal magnetic fields that, when combined, switch the magnetization orientation of the selected memory cell from parallel to anti-parallel or vice versa.

However, in the ultra-small device area, switching of the memory cells is not always reliable due to the superparamagnetic-ferromagnetic transition point in MRAMs. Sometimes, the combined magnetic fields might not cause a memory cell to switch reliably from parallel to anti-parallel, or vice-versa. Therefore, a need exists to improve reproducibility or reliability of switching MRAM devices without increasing the switching current.

### SUMMARY OF THE INVENTION

Broadly speaking, embodiments of the present invention address these needs by providing an MRAM cell that utilizes utilize MTJ devices having a perpendicular magnetic orientation. In one embodiment, an MRAM cell is disclosed. The MRAM cell includes a first wordline and a first bitline perpendicular to the wordline. Disposed at an intersection of the first wordline and the first bitline is an MTJ device having a perpendicular magnetic orientation. The MTJ device can include a free layer and a pinned layer, with the free layer being closer to the first bitline than the pinned layer. Optionally, a diode can be disposed below the MTJ device that is in electrical communication with the first wordline and the pinned layer. Adjacent to, and on either side of, the first bitline are a second bitline and a third bitline. Also, a second wordline and a third wordline are adjacent to and on either side of the first wordline. To program the MRAM cell, current can be driven through the second bitline and third bitline, and the second wordline and the third wordline. In this case, the current driven through the bitlines and through the wordlines is in opposite directions as described below.

A method for programming a MRAM cell having a magnetic junction tunnel MTJ device with a perpendicular magnetic orientation is disclosed in an additional embodiment of the present invention. Current is driven in a first direction through a first bitline, which is adjacent to a second bitline that is in electrical communication with the MRAM cell to be programmed. Current is also driven in a second direction through a third bitline that is adjacent to the second bitline and on a side opposite to the first bitline. The second direction is opposite the first direction. In this manner the MRAM cell is programmed to have a first magnetization orientation, which can represent either a “1” or a “0.” To program the MRAM cell to have a second magnetization orientation, current is driven in the second direction through the first bitline and in the first direction through the third bitline. In addition to the bitlines, current can be driven in a third direction through a first wordline, which is adjacent to a second wordline that is in electrical communication with the MRAM cell. Current can also be driven in a fourth direction through a third wordline that is adjacent to the second wordline and on a side opposite to the first wordline. As above, to program the MRAM cell to have a second magnetization orientation, current is driven in the fourth direction through the first wordline and in the third direction through the third wordline. To read the MRAM cell, current is driven through the second bitline and the second wordline.

An MRAM array is disclosed in a further embodiment of the present invention. The MRAM array includes a plurality parallel wordlines and parallel bitlines, with each bitline being perpendicular to the plurality of wordlines. At an intersection of a wordline and a bitline is disposed an MTJ device that has a perpendicular magnetic orientation. As above, each MTJ device can include a free layer and a pinned layer, wherein the free layer is closer to the bitlines than the pinned layer. Optionally, each MTJ device can be in electrical communication with a diode disposed below the MTJ device. In this case each diode is in electrical communication with the wordline and the pinned layer of the MTJ device.

Other aspects and advantages of the invention will become apparent from the following detailed description, taken in conjunction with the accompanying drawings, illustrating by way of example the principles of the invention.

### BRIEF DESCRIPTION OF THE DRAWINGS

The invention, together with further advantages thereof, may best be understood by reference to the following description taken in conjunction with the accompanying drawings in which:

FIG. 1 is a diagram showing an exemplary unit cell, in accordance with an embodiment of the present invention;

FIG. 2 is a diagram showing a portion of an MRAM memory cell array having MOS control, in accordance with an embodiment of the present invention;

FIG. 3 is a diagram showing an MRAM memory cell array having diode control, in accordance with an embodiment of the present invention;

FIG. 4A is a schematic diagram of the MRAM memory cell array illustrating a method for programming a unit cell to store a logic value 0;

FIG. 4B is a schematic diagram of the MRAM memory cell array illustrating a method for programming the unit cell to store a logic value 1;

FIG. 5 is a schematic diagram of the MRAM memory cell array illustrating a method for reading the unit cell;

FIG. 6 is a diagram showing adjacent unit cells, which illustrate the magnetic field distribution when programming unit cell;

FIG. 7 is a diagram illustrating the characteristic curve of a perpendicular MRAM, in accordance with an embodiment of the present invention;

FIG. 8 is a graph showing the shaped anisotropy induced stability, in accordance with an embodiment of the present invention;

FIG. 9A is a diagram showing a perpendicular pseudo spin-valve MTJ, in accordance with an embodiment of the present invention;

FIG. 9B is a diagram showing a perpendicular spin-valve MTJ, in accordance with an embodiment of the present invention;

FIG. 10 is a diagram showing exemplary properties of MRAM cells, in accordance with an embodiment of the present invention;

FIG. 11A is a diagram showing a three-dimensional view of an MRAM array having a shielding magnet, in accordance with an embodiment of the present invention; and

FIG. 11B is a diagram showing a side view of the MRAM array having a shielding magnet, in accordance with an embodiment of the present invention.

### DETAILED DESCRIPTION OF THE PREFERRED EMBODIMENTS

An invention is disclosed for an innovational method for fabricating an MRAM having high magnetic transition stability and low programming current. Embodiments of the present invention utilize MTJ devices having a perpendicular magnetic orientation. As a result, the MRAM of the present invention has high magnetic stability within the ultra-small device area. In addition, utilizing multiple-bitlines for programming, embodiments of the present invention greatly reduce the current required compared to that of conventional MRAM devices. In the following description, numerous specific details are set forth in order to provide a thorough understanding of the present invention. It will be apparent, however, to one skilled in the art that the present invention may be practiced without some or all of these specific details. In other instances, well known process steps have not been described in detail in order not to unnecessarily obscure the present invention.

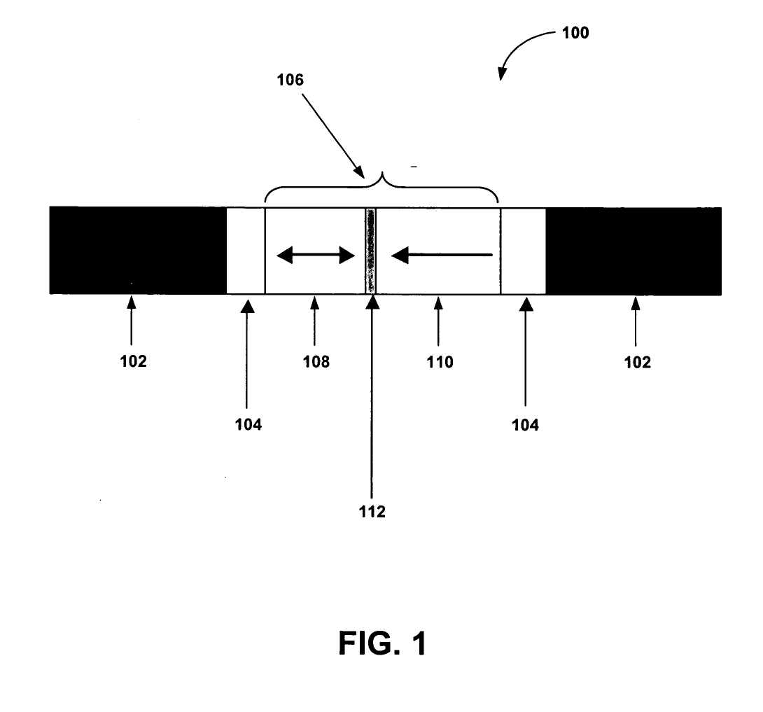

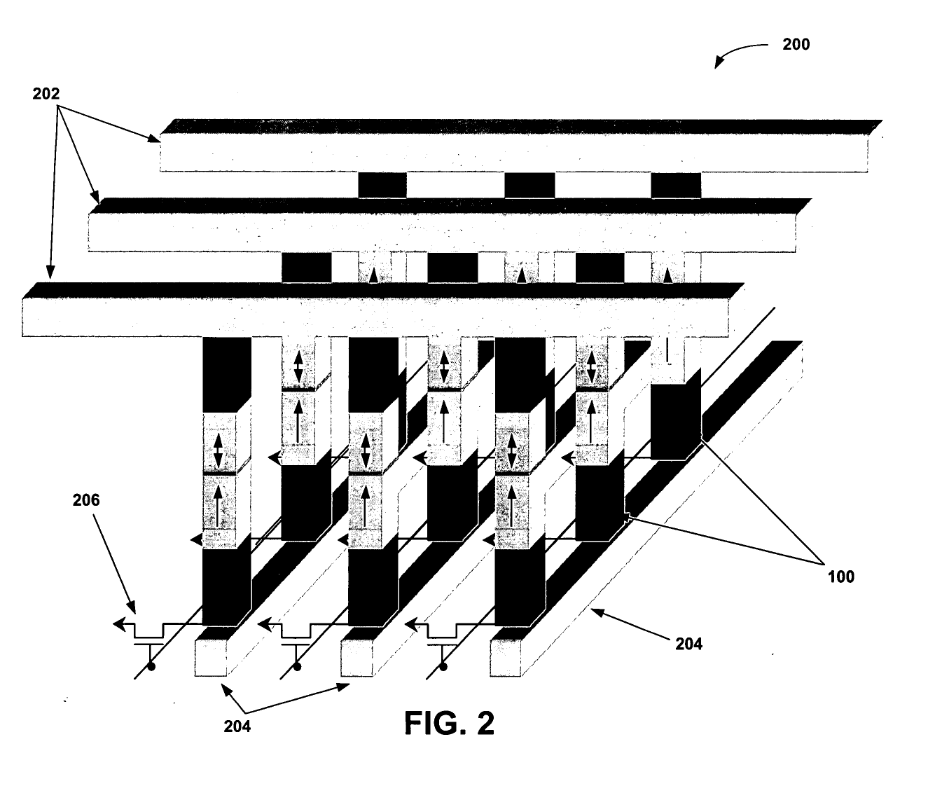

FIG. 1 is a diagram showing an exemplary unit cell 100, in accordance with an embodiment of the present invention. The exemplary unit cell 100 includes an MTJ device 106, disposed between two metal spacers 104, and two μ-metal regions 102. The MTJ device 106 includes a free layer 108 separated from a pinned layer 110 by an insulator 112. A plurality of unit cells 100 form the memory cells of the MRAM, and are accessed utilizing a plurality of bitlines and wordlines as illustrated next in FIG. 2.

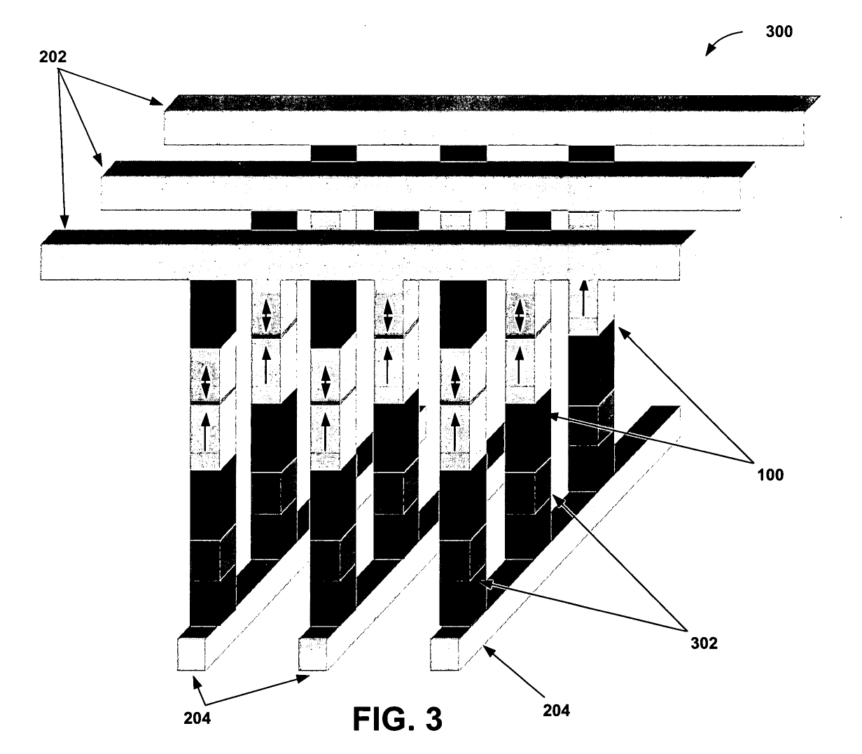

FIG. 2 is a diagram showing a portion of an MRAM memory cell array 200 having MOS control, in accordance with an embodiment of the present invention. The MRAM memory cell array 200 includes a plurality of unit cells 100 coupled together via a plurality of bitlines 202 and wordlines 204. The schematic transistor diagrams 206 illustrate the memory cells formed in the MRAM memory cell array 200. In addition to a MOS control memory cell array, embodiments of the present invention can be utilized to form a diode controlled memory cell array, as illustrated next with reference to FIG. 3.

FIG. 3 is a diagram showing an MRAM memory cell array 300 having diode control, in accordance with an embodiment of the present invention. As above, the MRAM memory cell array 300 includes a plurality of unit cells 100 coupled together via a plurality of bitlines 202 and wordlines 204. However, the MRAM memory cell array 300 includes a plurality of diodes 302, each disposed between the related unit cell 100 and the corresponding wordline 204.

As illustrated in FIGS. 2 and 3, embodiments of the present invention utilize MTJ devices having a perpendicular magnetic orientation, which results in the MRAM having high magnetic stability in the ultra-small device area. Advantageously, embodiments of the present invention address the superparamagnetic-ferromagnetic transition point issue occurring in conventional MRAM designs. That is, the superparamagnetic-ferromagnetic transition point issue no longer occurs in the ultra-small device area when utilizing the present invention because of the perpendicular shape anisotropic energy control. As a result, the size limitation of ferromagnetic phase in the embodiments of the present invention depends on the fundamental exchange coupling length that is around nm.

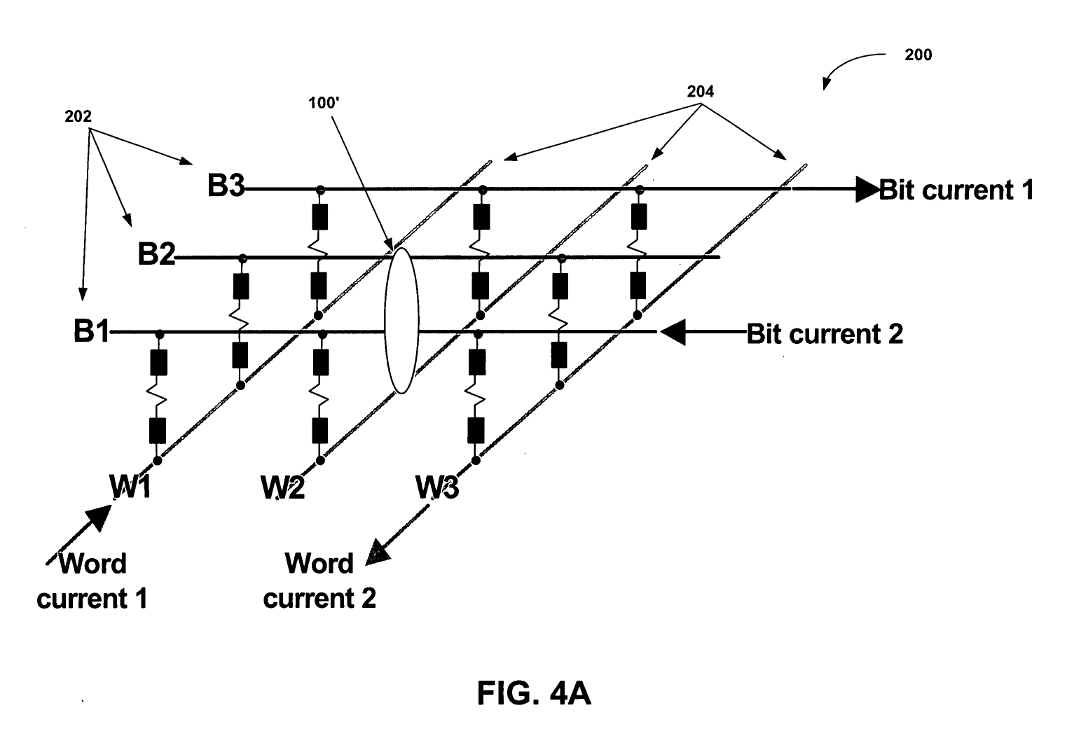

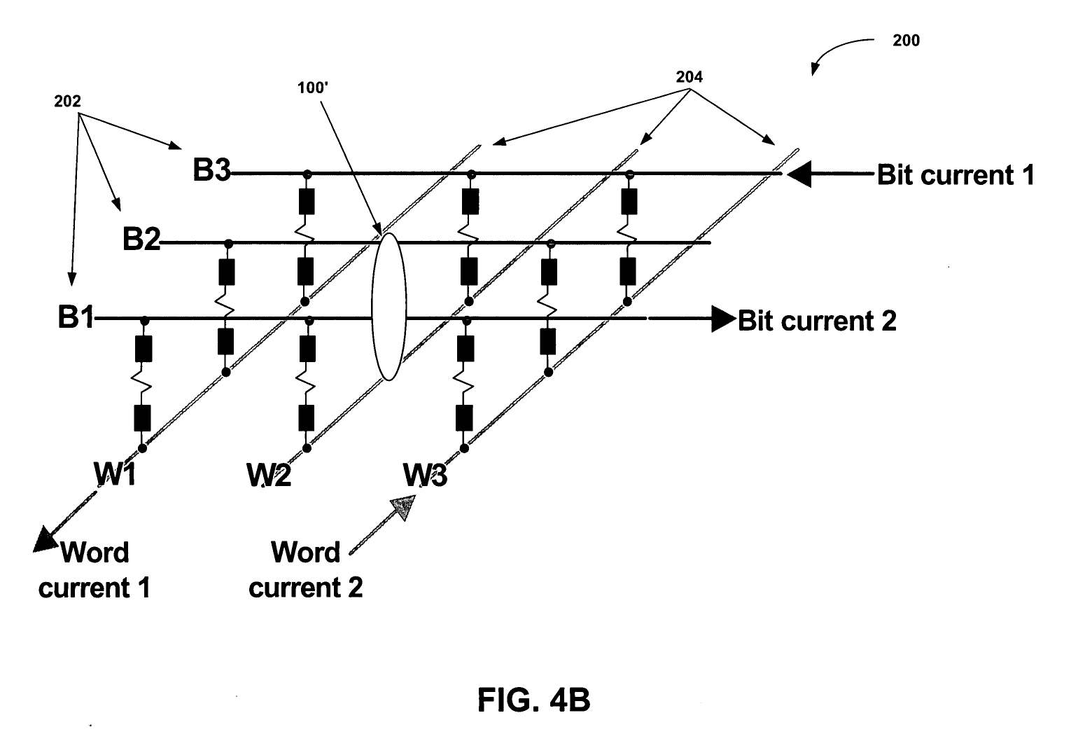

FIG. 4A is a schematic diagram of the MRAM memory cell array 200 illustrating a method for programming a unit cell 100′ to store a logic value 0. The unit cell 100′ is coupled to bitline B2 and wordline W2. As illustrated in FIG. 4A, bitlines B1 and B3 are disposed adjacent to bitline B2, which is coupled to unit cell 100′. In addition, wordlines W1 and W3 are formed adjacent to wordline W2, which also is coupled to unit cell 100′. To program unit cell 100′ to store a logic value 0, current is placed on bitlines B1 and B3 in the directions shown in FIG. 4A, which are opposite each other. In addition, current is placed on wordlines W1 and W3 in the directions shown in FIG. 4A, which are opposite each other.

FIG. 4B is a schematic diagram of the MRAM memory cell array 200 illustrating a method for programming the unit cell 100′ to store a logic value 1. To program unit cell 100′ to store a logic value 1 , current is placed on bitlines B1 and B3 in the directions shown in FIG. 4A, which are opposite each other. In addition, current is placed on wordlines W1 and W3 in the directions shown in FIG. 4A, which are opposite each other. It should be noted that the current directions on the bitlines 202 and the wordlines 204 when programming a logic value 1 are the inverse of the current directions on the bitlines 202 and the wordlines 204 when programming a logic value 0.

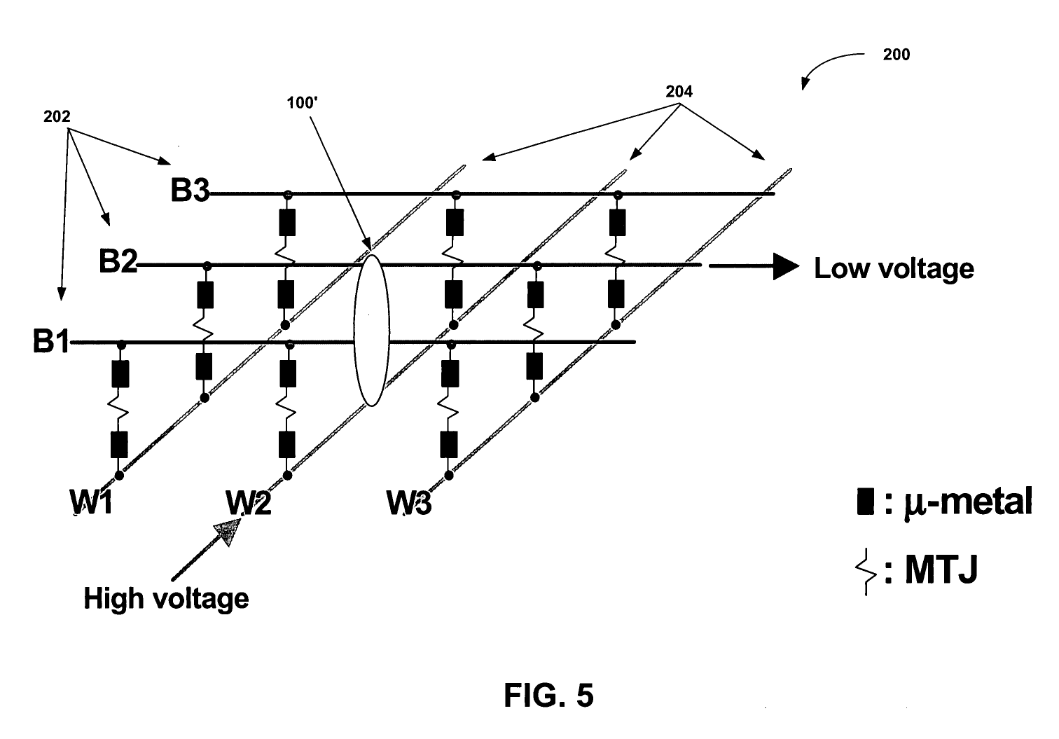

FIG. 5 is a schematic diagram of the MRAM memory cell array 200 illustrating a method for reading the unit cell 100′. When reading the unit cell 100′, current is placed on bitline B2 and wordline W2, both of which are coupled to the unit cell 100′. As illustrated in FIG. 5, multiple bitlines are not required when reading a unit cell. However, a higher voltage generally is utilized on the wordline W2 than on the related bitline B2.

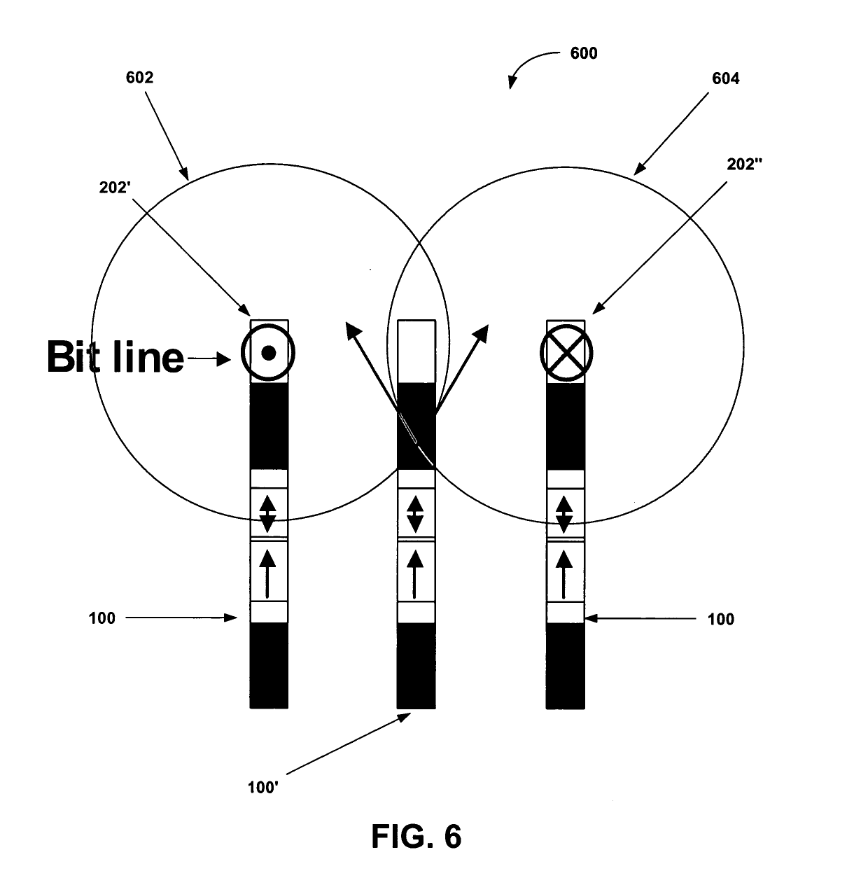

FIG. 6 is a diagram showing adjacent unit cells 100, which illustrate the magnetic field distribution when programming unit cell 100′. To program unit cell 100′, current is applied through bitline 202′ and bitline 20″ in opposite directions as illustrated in FIG. 6. Consequently, opposing magnetic fields are generated from the current flow through the bitlines 202′ and 202″. That is, the current flowing through bitline 202′ results in magnetic field 602 and the current flowing through bitline 202″ results in magnetic field 604. Thus, the in-plane field component of the magnetic fields 602 and 604 cancel each other. As a result, in-plane field noise does not disturb the memory state of unit cell 100′. In addition, the out-of-plane field component of the magnetic fields 602 and 604 is doubled due to the construction of the fields. As such, half the programming current through one bitline is required for the required field strength.

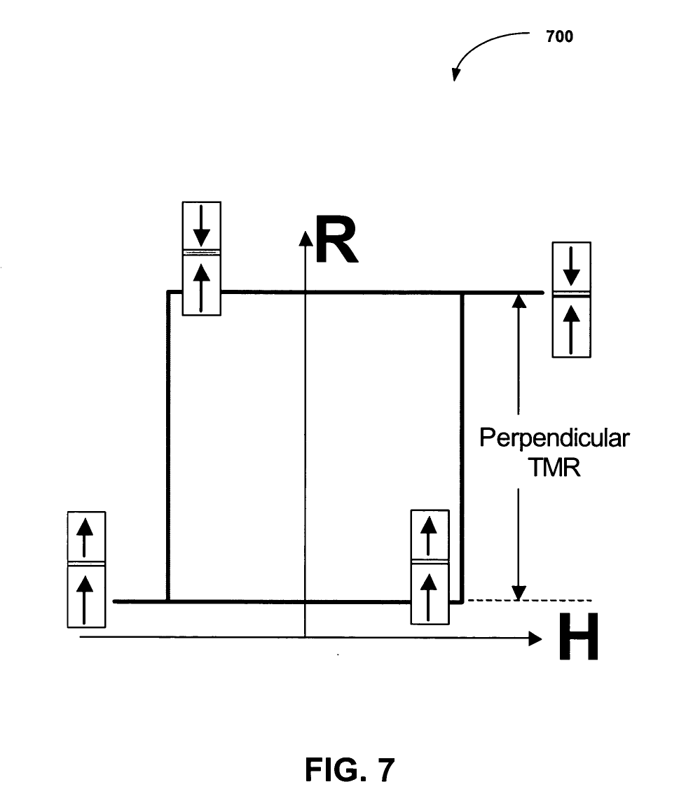

FIG. 7 is a diagram illustrating the characteristic curve 700 of a perpendicular MRAM, in accordance with an embodiment of the present invention. The pinned layer, for example bottom layer, has a fixed magnetic moment that is unchanged under the magnetic field cycle. The magnetic moment of the free layer can be controlled by the magnetic field and has a hysteresis property. The different relative moment orientation between the pinned and free layers shows the different tunneling resistance due to the spin-dependent tunneling effect, and thus the different voltage output or current output.

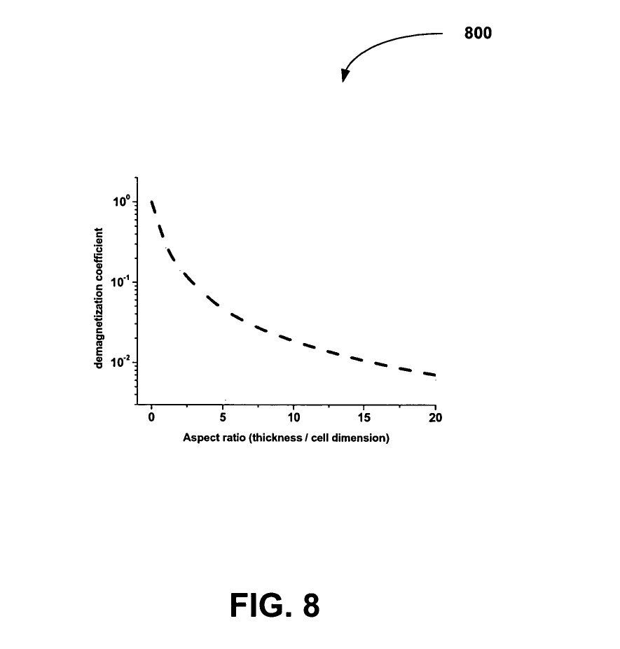

FIG. 8 is a graph 800 showing the shaped anisotropy induced stability, in accordance with an embodiment of the present invention. As shown in graph 800, the demagnetization field in the ferromagnetic layer decreases as the aspect ratio of ferromagnetic layer increases. Hence, the ferromagnetic layer has a more stable magnetic alignment. Equation (1) illustrates the demagnetization field:

$${H}_{d} = \frac{{NM}_{s}}{μ} , \qquad ( 1 )$$

where N is demagnetization coefficient, and Mₛ is magnetization of free layer.

For example, if N=10⁻¹ (aspect ratio ˜2.5 for rod shape), Mₛ=1000 G, and m=20, then H_{d}=5 Oe, which is much smaller than an H_{c} of around 50 Oe.

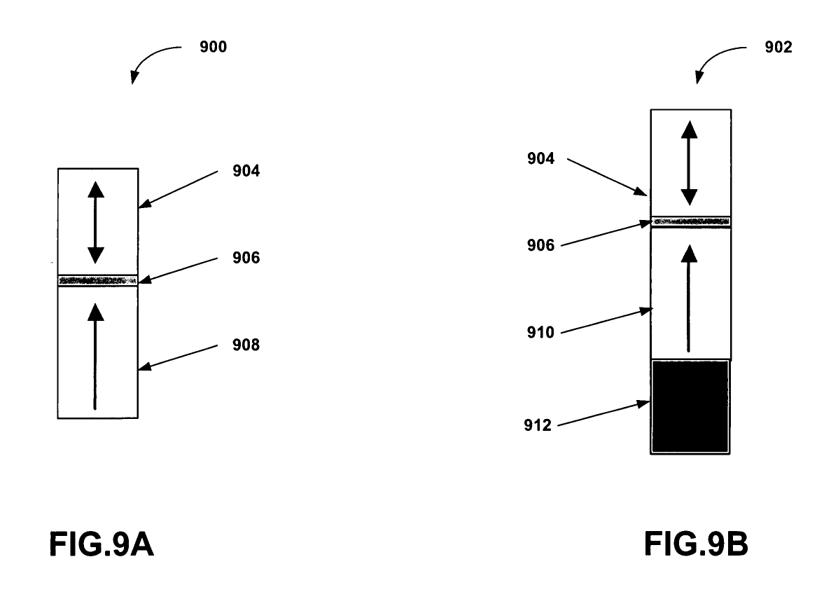

FIGS. 9A and 9B illustrate MTJ devices. FIG. 9A is a diagram showing a perpendicular pseudo spin-valve MTJ 900, in accordance with an embodiment of the present invention. The perpendicular pseudo spin-valve MTJ 900 includes a soft-magnet 904, also referred to as a free layer, and a hard-magnet 908. In addition, an insulator 906 is formed between the soft-magnet 904 and the hard-magnet 908. FIG. 9B is a diagram showing a perpendicular spin-valve MTJ 902, in accordance with an embodiment of the present invention. The perpendicular spin-valve MTJ 902 includes a soft-magnet 904, also referred to as a free layer, a pinned-magnet 910, and a pinned-layer 912. An insulator 906 is formed between the soft-magnet 904 and the pinned-magnet 910.

The free layer 904 of the perpendicular pseudo spin-valve MTJ 900 and the perpendicular spin-valve MTJ 902 can be a rare-earth-3d transition compound, such as GdFe, CoPt, FePt, thick Co with preference z-crystallization, ultra-thin (near 2-dimension, in-general, thinner than 1 nm) Fe, Co, and Ni, and their alloy, such as CoFe. The insulator 906 of the perpendicular pseudo spin-valve MTJ 900 and the perpendicular spin-valve MTJ 902 can be a thin oxide or nitride, such as Al₂O₃, AIN, AION, Ga₂O₃, HfO₂, STO, etc. The thickness is less than 3 nm. The pinning layer 912 of the perpendicular spin-valve MTJ 902 can be a synthetic antiferromagnetic multilayer (SAF), such as (free layer/Ru (0.7˜0.8 nm)/free layer) etc, or antiferromagnetic material with perpendicularly orientated magnetization, such as IrMn, FeMn, PtMn, etc, or remnant magnet, such as SmCo, etc.

Using the embodiments of the present invention, the thickness of the metal spacer is smaller and a high permeability metal can be easily switch the magnetic moment of the free layer 904, allowing the writing current to be smaller. The reduction of the writing current is mainly reached by the deposition technique, not by the photo-technique. The metal spacer can be non-magnetic conductive metal, such as Ta, Al, W, Cu, Pt, etc, which can also form the buffer or capping layer of MTJ.

The writing magnet can be a soft ferromagnet that is permalloy or supermalloy, such as NiFe, NiFeMo, NiFeCu, NiFeCr, NiFeCuMo, or Fe-TM-B system (TM=IV˜VIII group transition metal), such as Fe—Co—Ni—Zr—Ta—B, or Fe—(Al, Ga)—(P, C, B, Si) or Fe—(Co, Ni)—Zr—B, or Fe—(Co, Ni)—(Zr, Nb)—B, or Fe—(Co, Ni)—(Mo, W)—B, or Fe—Si—B, or Fe—Si—B—Nb—Cu, or Fe—Si—B—Nb, or Fe—Al—Ga—P—C—B—Si, or Fe—Co—Si—B—Cu—Nb, or Fe—Co—Ni—S, Co—Nb—Zr, or Fe—Zr—Nb—B, or Hiper50, or sendust, or FeTaC, or Fe—Ta—N—C etc magnetic alloy with a coercivity of 1˜0.001 Oe and a permeability of 1000˜1,000,000.

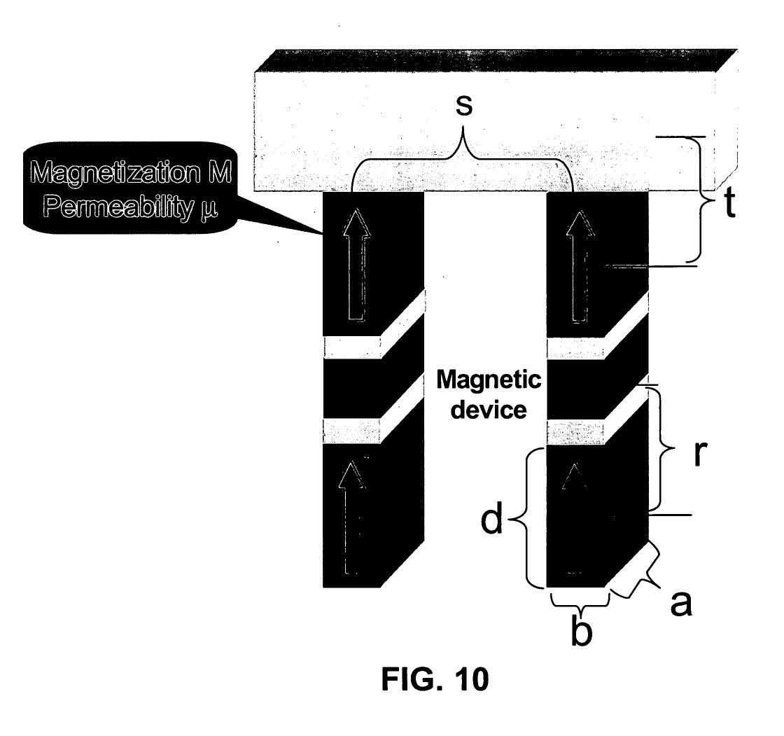

FIG. 10 is a diagram showing exemplary properties of MRAM cells, in accordance with an embodiment of the present invention. Equation (2) describes the relations of FIG. 10:

$$H = \frac{2 π}{25} \times \frac{s ( {I}_{x} + {I}_{y} )}{{( \frac{d}{2} + t )}^{2} + {s}^{2}} \times χ \times ( \frac{{( r + \frac{d}{2} )}^{2}}{{( r + \frac{d}{2} )}^{2} + \frac{{a}^{2} + {b}^{2}}{4}} - \frac{{( r - \frac{d}{2} )}^{2}}{{( r - \frac{d}{2} )}^{2} + \frac{{a}^{2} + {b}^{2}}{4}} ) ( O e ) \qquad ( 2 )$$

For example, when μ-metal (χ=10,000) with 4,000 Å thickness and dimension of 0.1 μm, the spacer between cells is 0.1 μm, r=0.3 μm, t=0.4 μm, and the coercive field of free layer is 50 Oe, then the required current in one line is 8 μA. The total required current (×4) is 32 μA. When programming, the metal line has current density of 2×10⁴ A/cm². Compared to conventional MRAM structures, embodiments of the present invention improve the current density degradation about order of magnitude of 4, based on the χ value of μ-metal.

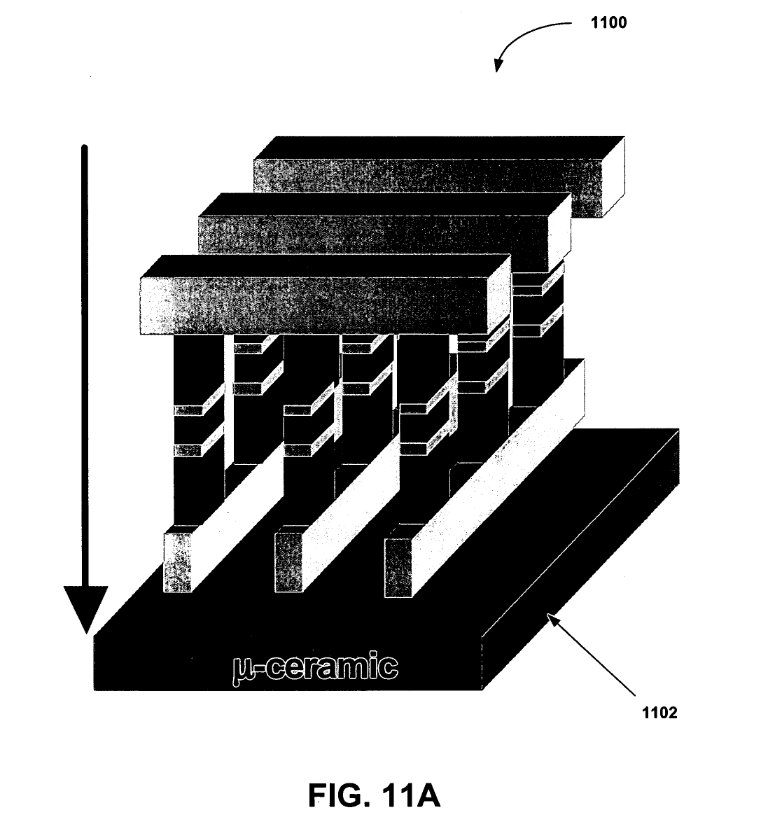

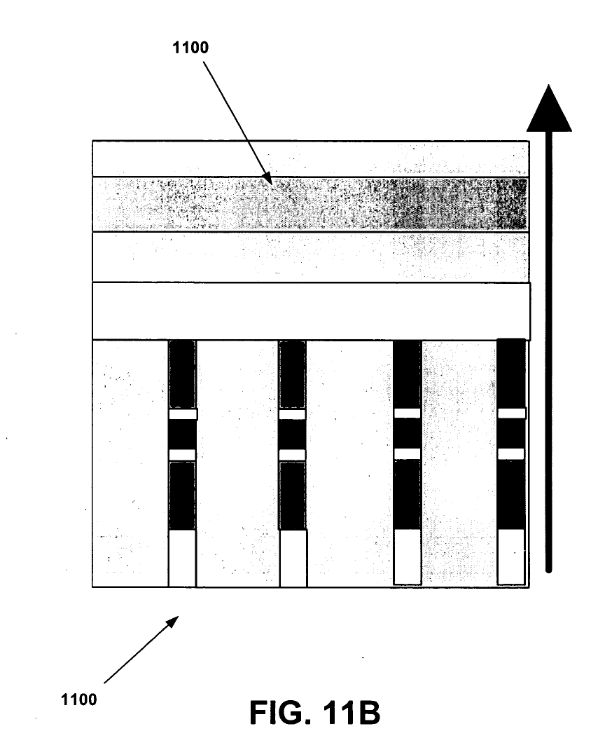

FIG. 11A is a diagram showing a three-dimensional view of an MRAM array 1100 having a shielding magnet 1102, in accordance with an embodiment of the present invention. FIG. 11B is a diagram showing a side view of the MRAM array 1100 having a shielding magnet 1102, in accordance with an embodiment of the present invention. The shielding magnet 1102 prevents magnetic noise from the environment, and buffers the magnetic flux of the p-metal when programming the unit cells. The shielding magnet 1102 is a magnetic ceramic material such as (MnO)(Fe₂O₃), (ZnO)(Fe₂O₃), (MnO)(ZnO)(Fe₂O₃), etc. The resistivity of the magnetic ceramic material generally is in the range of 10¹³ W-cm, which is an insulator matrix. The permeability of these materials ranges around several thousand. For example, if (MnO)₃₁(ZnO)₁₁(Fe₂O₃)₅₈, m ranges 1000˜2000 below 200° C.

During fabrication, the magnetic ceramic is directly deposited with O₂ ambient by target that the O-atom has been added, and then an annealing process is performed. Then, using a hydrothermal method, nitrate solutions of Zn, Mn, and Fe are mixed, and then alkalinity is tuned and then 150° C. treatment for 0.5˜16 hours and then precipitating is performed by aqueous ammonia. Finally, using a citric acid precursor method, citric acid is added into aqueous nitrates of Fe, Mn, or Zn, and then pH value is adjusted by NH₄OH. After adding glycol and raising temperature to 80° C., esterification causes solid precursors. Crystalline MnFe₂O₄ is obtained at 350° C.

Although the foregoing invention has been described in some detail for purposes of clarity of understanding, it will be apparent that certain changes and modifications may be practiced within the scope of the appended claims. Accordingly, the present embodiments are to be considered as illustrative and not restrictive, and the invention is not to be limited to the details given herein, but may be modified within the scope and equivalents of the appended claims.

1. A magnetic random access memory (MRAM) cell, comprising:
a first wordline;
a first bitline perpendicular to the wordline; and
a magnetic tunnel junction (MTJ) device disposed at an intersection of the first wordline and the first bitline, the MTJ device having a perpendicular magnetic orientation.

2. An MRAM cell as recited in claim 1, wherein the MTJ device includes a free layer and a pinned layer, the free layer being closer to the first bitline than the pinned layer.

3. An MRAM cell as recited in claim 2, further comprising a diode disposed below the MTJ device, the diode being in electrical communication with the first wordline and the pinned layer.

4. An MRAM cell as recited in claim 1, wherein a second bitline and a third bitline are adjacent to and on either side of the first bitline, and a second wordline and a third wordline are adjacent to and on either side of the first wordline.

5. An MRAM cell as recited in claim 4, wherein the MRAM cell is programmed by driving current through the second bitline and third bitline, and the second wordline and the third wordline.

6. An MRAM cell as recited in claim 5, wherein the current driven through the second bitline is in an opposite direction to the current driven through the third bitline.

7. An MRAM cell as recited in claim 6, wherein the current driven through the second wordline is in an opposite direction to the current driven through the third wordline.

8. A method for programming a magnetic random access memory (MRAM) cell having a magnetic junction tunnel (MTJ) device with a perpendicular magnetic orientation, comprising the operations of:
driving current in a first direction through a first bitline, the first bitline being adjacent to a second bitline that is in electrical communication with the MRAM cell; and
driving current in a second direction through a third bitline, the third bitline being adjacent to the second bitline and on a side opposite to the first bitline, wherein the second direction is opposite the first direction,
wherein the MRAM cell is programmed to have a first magnetization orientation.

9. A method as recited in claim 8, wherein driving current in the second direction through the first bitline, and driving current in the first direction through the third bitline programs the MRAM cell to have a second magnetization orientation.

10. A method as recited in claim 8, further comprising the operations of:
driving current in a third direction through a first wordline, the first wordline being adjacent to a second wordline that is in electrical communication with the MRAM cell; and
driving current in a fourth direction through a third wordline, the third wordline being adjacent to the second wordline and on a side opposite to the first wordline, wherein the fourth direction is opposite the first direction,
wherein the MRAM cell is programmed to have the first magnetization orientation.

11. A method as recited in claim 10, wherein driving current in the fourth direction through the first wordline, and driving current in the third direction through the third wordline programs the MRAM cell to have the second magnetization orientation.

12. A method as recited in claim 8, wherein the MRAM cell is read by driving current through the second bitline and driving current through the second wordline.

13. A method as recited in claim 8, wherein the current flowing in the first direction on the first bitline generates a magnetic field having a first in-plane component, and wherein the current flowing in the second direction on the second bitline generates a magnetic field having a second in-plane component.

14. A method as recited in claim 13, wherein the first in-plane component cancels out the second in-plane component.

15. A magnetic random access memory (MRAM) array, comprising:
a plurality parallel wordlines and parallel bitlines, each bitline being perpendicular to the plurality of wordlines;
a plurality of magnetic tunnel junction (MTJ) devices, each MTJ device disposed at an intersection of a wordline and a bitline, wherein each MTJ device has a perpendicular magnetic orientation.

16. An MRAM array as recited in claim 15, wherein each MTJ device includes a free layer and a pinned layer, the free layer being closer to the bitlines than the pinned layer.

17. An MRAM cell as recited in claim 16, wherein each MTJ device is in electrical communication with a diode disposed below the MTJ device, each diode being in electrical communication with a wordline and the pinned layer of the MTJ device.

18. An MRAM array as recited in claim 15, wherein each MTJ device is programmed by driving current through two adjacent bitlines and two adjacent wordlines.

19. An MRAM array as recited in claim 17, wherein current is driven through the adjacent bitlines in opposite directions.

20. An MRAM array as recited in claim 18, wherein current is driven through the adjacent wordlines in opposite directions.
